(19) United States
(12) Patent Application Publication
(10) Pub. No.: US 2019/0086953 A1
(43) Pub. Date: Mar. 21, 2019

(54) DEVICE FOR PROTECTING PORTABLE COMPUTER

(71) Applicant: Michael E. CHAVANNES, Menomonee Falls, WI (US)

(72) Inventor: Michael E. CHAVANNES, Menomonee Falls, WI (US)

(21) Appl. No.: 16/085,473

(22) PCT Filed: Mar. 17, 2017
(86) PCT No.: PCT/US2017/023008

§ 371 Date: Sep. 14, 2018

Related U.S. Application Data
(60) Provisional application No. 62/309,860, filed on Mar. 17, 2016.

(51) Int. Cl. G06F 1/16; H05K 5/03

(52) U.S. Cl. CPC G06F 1/1607; H05K 5/03; G06F 1/1656

(57) ABSTRACT

A protective cover for a portable computer has a central core and an outer shell. The perimeter of the outer shell has a pair of opposed major edges which define its width and a pair of opposed minor edges which define its length. An adhesive strip with a height less than its width is placed on the outer shell so that its width is parallel to the pair of opposed major edges. The adhesive strip is spaced from one of the opposed major edges by approximately one-half the adhesive strip's height and is spaced from one of the opposed minor edges by a distance of approximately the adhesive strip's height.

This application is being filed on Mar. 17, 2017, as a PCT International Patent application and claims priority to U.S. Provisional patent application Ser. No. 62/309,860, filed Mar. 17, 2016, the entire disclosure of which is incorporated by reference in its entirety.

### INTRODUCTION

Portable laptop computers can be subjected to abuse during transport and usage. Often, this abuse can cause the screen of the computer to be damaged, thus necessitating replacement thereof.

### SUMMARY

In one aspect, the technology relates to a protective cover for a portable computer, the protective cover having: a central core having a first material; an outer shell disposed about the central core, wherein the outer shell has a perimeter having a pair of opposed major edges and a pair of opposed minor edges, and wherein the outer shell has a second material different than the first material, and wherein the pair of opposed major edges defines an outer shell width therebetween, and wherein the pair of opposed minor edges defines an outer shell length therebetween; and an adhesive strip disposed on a first side of the outer shell, wherein the adhesive strip has an adhesive strip width and an adhesive strip height less than the adhesive strip width, wherein the adhesive strip is disposed such that the adhesive strip width is substantially parallel to the pair of opposed major edges, and wherein the adhesive strip is spaced from at least one of the pair of opposed major edges by a first spacing substantially one-half the adhesive strip height, and wherein the adhesive strip is spaced from at least one of the pair of opposed minor edges by a second spacing approximately equal to the adhesive strip height. In an embodiment, the second spacing does not exceed the adhesive strip height. In another embodiment, the adhesive strip height is approximately one-half inch. In yet another embodiment, the adhesive strip has two adhesive strips, wherein the two adhesive strips are disposed proximate a single one of the pair of opposed major edges. In yet another embodiment, the two adhesive strips are separated from each other by a gap having a gap distance of less than the adhesive strip width. In still another embodiment, the adhesive strip has four adhesive strips, wherein a first two of the four adhesive strips are disposed proximate a first one of the pair of opposed major edges, and wherein a second two of the four adhesive strips are disposed proximate a second one of the pair of opposed major edges.

In another embodiment of the above aspect, a single one of the pair of opposed major edges is connected to a single one of the pair of opposed minor edges at a curved portion of the perimeter, wherein the curved portion of the perimeter has a radius substantially similar to the second spacing. In an embodiment, the first material is plastic and wherein the second material is metal. In another embodiment, the first material is PVC and wherein the second material is aluminum. In yet another embodiment, the second material has a substantially erasable writing surface.

In another aspect, the technology relates to a protective cover for a portable computer, the protective cover having: a shell having a perimeter defined at least in part by a major edge and a minor edge and a curved edge joining the major edge and the minor edge; and an adhesive strip having an elongate axis, wherein the elongate axis is disposed substantially parallel to the major edge, and wherein outer edges of the adhesive strip are disposed a first distance from the major edge and are disposed a second distance from the minor edge, wherein the second distance is greater than the first distance, and wherein the second distance is substantially similar to a height of the adhesive strip. In an embodiment, the shell substantially surrounds a core material different than the shell. In another embodiment, the curved edge has a radius substantially the same as the second distance. In yet another embodiment, the adhesive strip has a strip width at least about approximately one-third of a length of the major edge. In still another embodiment, the adhesive strip has a removable cover.

In another embodiment of the above aspect, the second distance is no more than substantially double the first distance. In an embodiment, the first distance is about one-quarter inch. In another embodiment, the perimeter includes four curved edges. In yet another embodiment, the adhesive strip includes four adhesive strips, wherein a single one of the four adhesive strips is disposed proximate a single one of the four curved edges. In still another embodiment, the adhesive strip includes a foam material.

### BRIEF DESCRIPTION OF THE DRAWINGS

There are shown in the drawings, examples which are presently preferred, it being understood, however, that the technology is not limited to the precise arrangements and instrumentalities shown.

FIG. 1 is a perspective view of a portable computer.

FIGS. 2A and 2B are a bottom view and an enlarged partial bottom view, respectively, of a prior art protective cover for a portable computer.

FIGS. 3A and 3B are a bottom view and an enlarged partial bottom view, respectively, of a protective cover in accordance with an example of the technology for a portable computer.

FIG. 4 is an enlarged partial section view of a portable computer including a protective cover.

### DETAILED DESCRIPTION

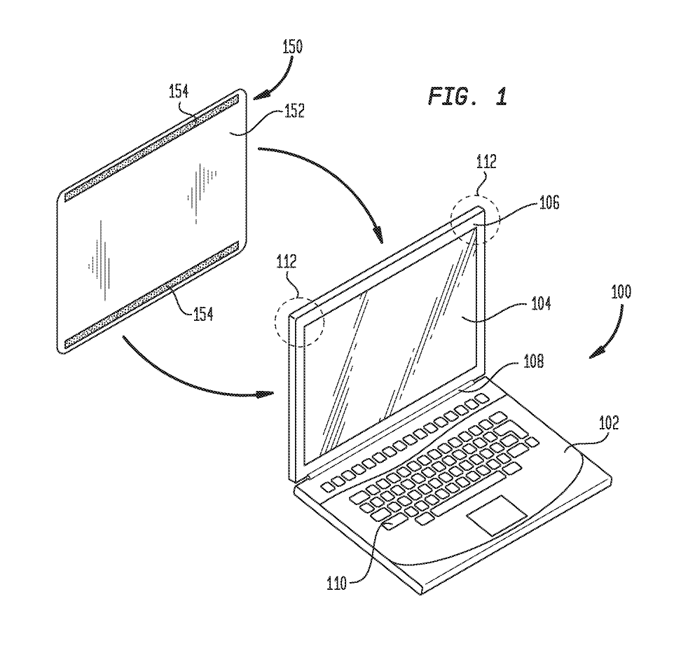

FIG. 1 is a perspective view of portable computer 100. The computer 100 includes a body 102 and a screen 104 disposed in a screen housing 106 that is pivotably connected to the body 102 at a hinge 108. The hinge 108 allows the computer 100 to be opened and closed so as to view the screen 104. The body 102 houses one or more processors (not shown), a keyboard 110, and other components to operate the computer 100. The portable nature of the computer 100 can expose the computer 100 to damage due to dropping, inappropriate gripping, or other factors. In fact, portable computers used in school environments are subject to significant abuse from young students who often do not consider the consequences of their actions or interactions with the computer. For example, students often grip the computer 100 by the upper corners 112 of the screen housing 106. This can cause damage to the screen 104, since the screen housing 106 is often a thin plastic. This damage can be in the form of a cracked screen 104, inoperable or damaged pixels, etc.

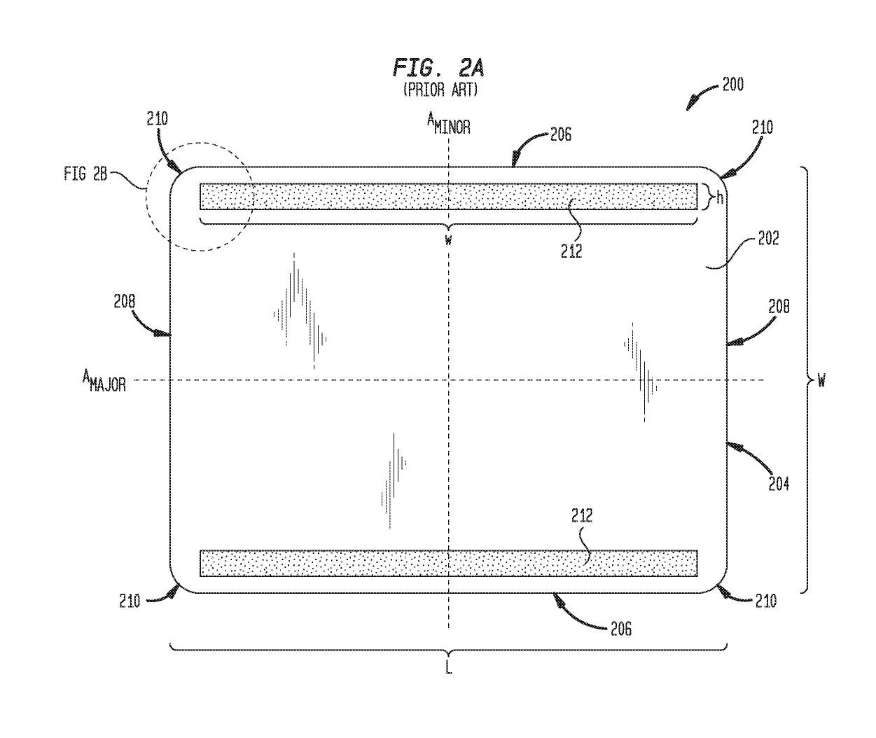

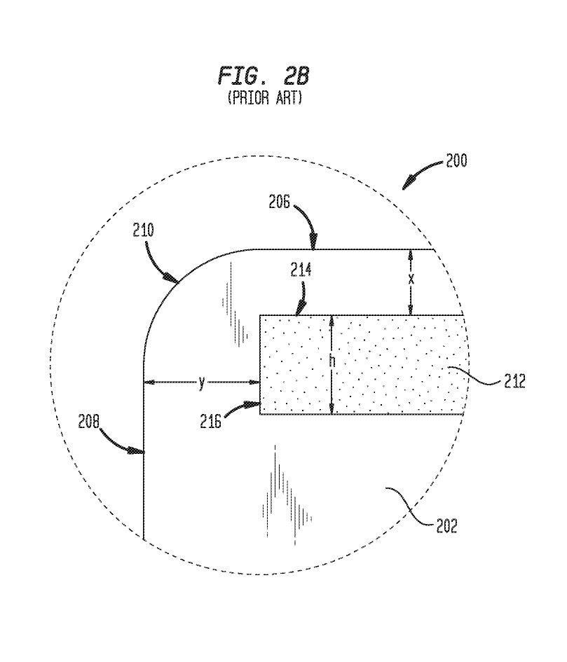

To attempt to counter this damage, protective covers such as cover 150 may be applied to the screen housing 106, specifically a rear portion thereof. A number of different covers are available on the market, but all display some type of shortcoming that limits the amount of protection the cover 150 can provide to the screen 104. One such prior art cover 150 is manufactured by CTL and includes a protective plate 152 having disposed thereon a plurality of adhesive strips 154. The adhesive strips 154 are used to secure the plate 152 to a rear portion of the screen housing 106. This allows the cover 150 to reinforce the screen housing 106 so as to prevent damage to the screen 104 caused by gripping of the corners 112 or by dropping of objects onto the closed computer 100 (e.g., onto the cover 150). One such prior art cover is depicted and described in more detail with regard to FIGS. 2A and 2B.

FIGS. 2A and 2B are a bottom view and an enlarged partial bottom view, respectively, of a prior art protective cover 200 for a portable computer. FIGS. 2A and 2B are described substantially simultaneously. The cover 200 includes a plate 202 that may be dimensioned as required or desired for a particular application. Typically, these dimensions include a length L and a width W that may be consistent with the screen housing to which the cover 200 is secured. The plate 202 includes a perimeter 204 having a plurality of edges. Here, the edges include two opposed major edges 206 and two opposed minor edges 208. Corner edges 210 form the intersections of adjacent major edges 206 and minor edges 208, which may intersect at approximately orthogonal angles, chamfers, or smooth radii (as depicted). The major edges 206 are substantially parallel to a major axis A_{MAJOR}, while the minor edges 208 are substantially parallel to a minor axis A_{MINOR}. These axes may define the length L and width W of the plate 202. Two adhesive strips 212 are secured proximate the major edges 206. In this prior art example, the adhesive strips 212 are VHB™ tape manufactured by 3M Corp, of St. Paul, Minn. Each adhesive strip 212 has a height h and a width w.

The adhesive strip 212 may be positioned so as to adhere the plate 202 to a rear of the screen housing. Positioning thereof is depicted best in FIG. 2A, where the adhesive strip 212 includes a wide edge 214 and a narrow edge 216. The wide edge 214 is disposed proximate and substantially parallel to the major edge 206, while the narrow edge 216 is disposed proximate and substantially parallel to the minor edge 208. In this prior art cover 200, the major edge 206 and the wide edge 214 are separated by a distance x, where

x=h/2 (1)

and the minor edge 208 and the narrow edge 216 are separated by a distance y, where

y≈2h (2)

As such, for an adhesive strip 212 having a height h of approximately 0.5″, distance y is equal to approximately 1.0″. Absence of the adhesive strip 212 in the area defined by distance y allows for a separation or gap between the plate 202 and the screen housing. While it was believed that the gap provided the ability for the plate 202 to deflect to absorb impact and other forces, it has been discovered that the performance of such a configuration is generally unacceptable. The technologies described herein below greatly improve upon the teachings of this prior art protective cover 200 to provide significantly better performance.

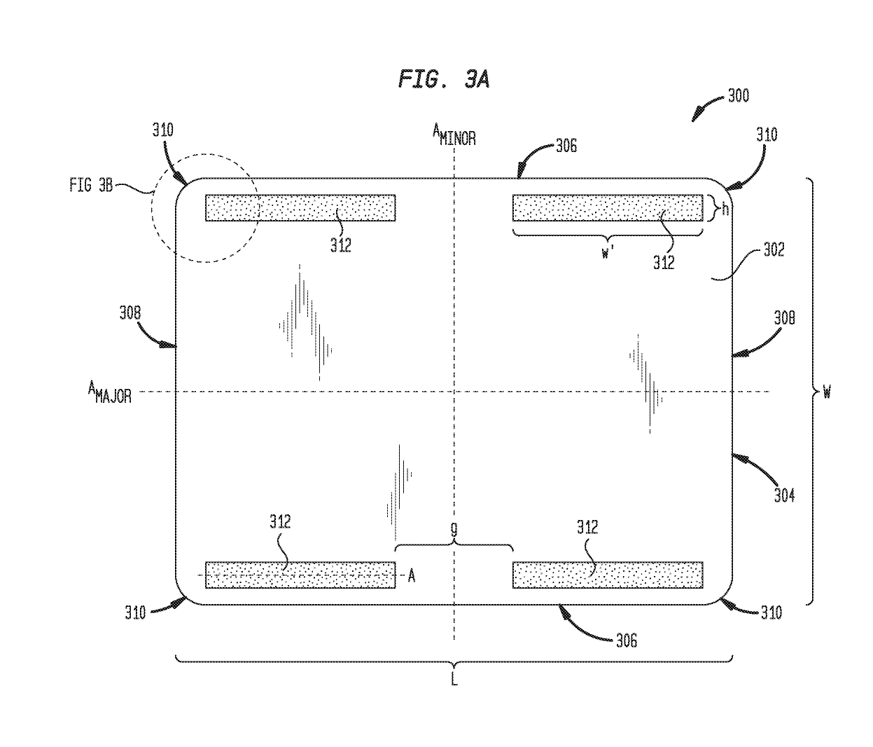

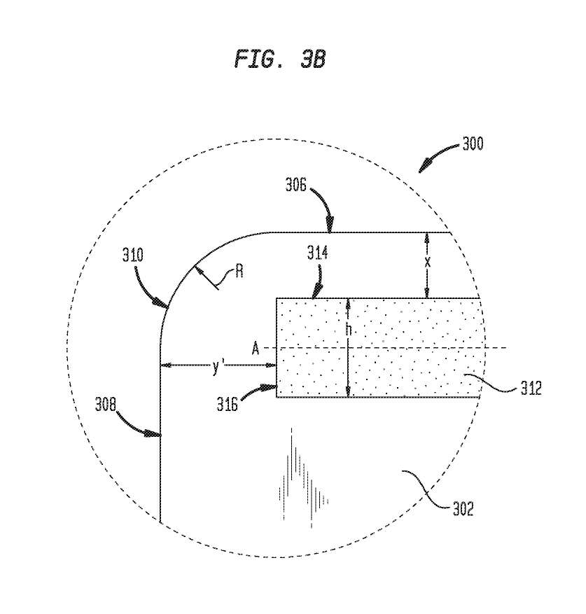

FIGS. 3A and 3B are a bottom view and an enlarged partial bottom view, respectively, of a protective cover 300 in accordance with an example of the technology, for a portable computer. FIGS. 3A and 3B are described substantially simultaneously. The cover 300 includes a plate 302 that may be dimensioned as required or desired for a particular application. In the depicted example, the plate 302 may be manufactured so as to have a PVC core with an aluminum outer shell sandwiching or surrounding the core. Such material is available as an aluminum veneer board under the name of Dibond™, manufactured by 3A Composites USA, Inc., of Statesville, N.C. Typically, the dimensions of the plate 302 include a length L and a width W that may be consistent with the screen housing upon which the cover 300 is secured. For example, the length L may be between about 279 mm to about 356 mm, depending on the size of the screen housing. The width W may be between about 178 mm and about 255 mm. A thickness of the plate may be about 2.0 mm.

The plate 302 includes a perimeter 304 having a plurality of edges that include two opposed major edges 306 and two opposed minor edges 308. Corner edges 310 form the intersections of adjacent major edges 306 and minor edges 308, which may intersect at approximately orthogonal angles, chamfers, or smooth radii (as depicted). The major edges 306 are substantially parallel to a major axis A_{MAJOR}, while the minor edges 308 are substantially parallel to a minor axis A_{MINOR}. These axes can define the length L and width W of the plate 302. Unlike the prior art cover depicted above in FIGS. 2A and 2B, four adhesive strips 312 are secured proximate the major edges 306 and in certain cases proximate each of the curved edges 310. The adhesive strips 312 are TWIN STICK™ foam adhesive tapes, available from Essentra Specialty Tapes, of Forest Park, Ill. Each adhesive strip 312 has a height h and a width w′. The width w′ may be about one third of the length L. In this example, the adhesive strip 312 may have a height h of about 0.5″ and have a foam thickness of about 0.73 mm. Although VHB™ tape may be utilized, it has been determined that TWIN STICK™ tape displays more desirable adhesion across a wider range of temperatures. In the example, four adhesive strips 312 are utilized to reduce the total amount of adhesive tape required, without sacrificing performance. In other examples, two adhesive strips 312 (as depicted in FIG. 2A may also be utilized).

The adhesive strips 312 may be positioned so as to adhere the plate 302 to the screen housing. Positioning thereof is depicted best in FIG. 3A. There, the adhesive strip 312 includes a wide edge 314 and a narrow edge 316. The wide edge 314 is disposed proximate and substantially parallel to a major edge 306, while the narrow edge 316 is disposed proximate and substantially parallel to a minor edge 308. In another example, the wide edge 314 is disposed proximate and substantially parallel to a minor edge 308, while the narrow edge 316 is disposed proximate and substantially parallel to a major edge 306. In another example, the strips may be parallel as defined by a position of a strip axis A. In the depicted cover 300, the major edge 306 and the wide edge 314 are separated by a distance x, where is as calculated in Equation (1) above. The minor edge 308 and the narrow edge 316 are separated by a distance y′, where

y′≈h (3)

As such, for an adhesive strip 312 having a height h of approximately 0.5″, distance y′ is equal to approximately 0.5″. Surprising, this minor change from distance y to distance y′ provides an unexpected and marked increase in performance. Moreover, it may be desirable for the radius R of the curved edge 310 to match an associated radius of the screen housing. In this case,

R=y′ (4)

which also has been determined to help reduce damage to the screen. The values of x, y′, and R may vary. For example, y′ may be exactly twice the height h. In another example y′ may not exceed double the height h. The adhesive strips 312 may be separated by a gap g where

g<w′ (5)

### EXAMPLE AND COMPARATIVE TESTING

In order to prove improved performance by the change in placement of the adhesive strips, testing was performed. The testing included, in general, securing covers to a portable computer using adhesive strips. Two covers were utilized, and the adhesive strips were located in different locations thereon (more specifically, the adhesive strips were spaced from the minor edges by different distances). Once the cover was secured, the portable computer was closed and a series of weights having progressively higher values were dropped from a predetermined height onto a corner of the cover. After each impact, the screen was viewed to detect damage. The testing materials and conditions were identical, other than the adhesive strip length 1 and distance y, y′ (as those terms are depicted and described in the context of FIGS. 2B and 3B) so as to make a valid comparison. A more detailed description of the equipment used and the testing procedure follows.

Portable Computer Model: Acer 720c

Protective Cover Size: 288 mm×204 mm

Protective Cover Material: Dibond™ (aluminum veneer PVC board)

Protective Cover Thickness: 2.0 mm

Adhesive Strip Material: VBH™ tape (with removable cover)

Adhesive Strip height h (per FIG. 2B or 3B): 0.5″

Distance×(per FIG. 2B or 3B): 0.25″

Adhesive Strip width w or w′ (per FIG. 2A or 3A): See below

Distance y or y′ (per FIG. 2B or 3B): See below

Weight Drop Height: 4.0″

Weights Tested: 2.5 lb., 5 lb., 10 lb., 25 lb.

Two adhesive strips were used (similar to the configuration depicted in FIG. 2A). In Test A, the adhesive strips were placed such that distance y was approximately 1.0″ (approximately 25 mm). As such, the adhesive strip width w in Test A was 238 mm (288 mm−25 mm−25 mm). In Test B, the adhesive strips were placed such that distance y′ was approximately 0.5″ (approximately 13 mm). As such, the adhesive strip width w′ in Test A was 262 mm (288 mm−13 mm−13 mm). Weights were dropped on each cover (specifically at a distance of about 1″ from a corner edge of the protective cover). The results are depicted in Table 1 below.

TABLE 1
Drop Test Results

| | Adhesive | | 2.5 lb | 5 lb | 10 lb | 25 lb |
|---|---|---|---|---|---|---|
| | Strip | | Weight | Weight | Weight | Weight |
| | Width | Distance | Drop | Drop | Drop | Drop |
| Test | w or w′ | y or y′ | Test | Test | Test | Test |
| A | 238 mm | 1.0 inch | PASS | FAIL | UN- | UN- |
| | | | | | TESTED | TESTED |
| B | 262 mm | 0.5 inch | PASS | PASS | PASS | PASS |

As can be seen from Table 1, the Test B placement of the adhesive strip (e.g., where the narrow edge is a distance y′ of approximately 0.5″ from the edge of the cover) displays significantly higher resistance to impact than the adhesive strip placed in the Test A placement position. Based on the limited testing performed above, an adhesive strip placed as in Test B can withstand at least 10 times the impact force as the adhesive strip placed as in Test A.

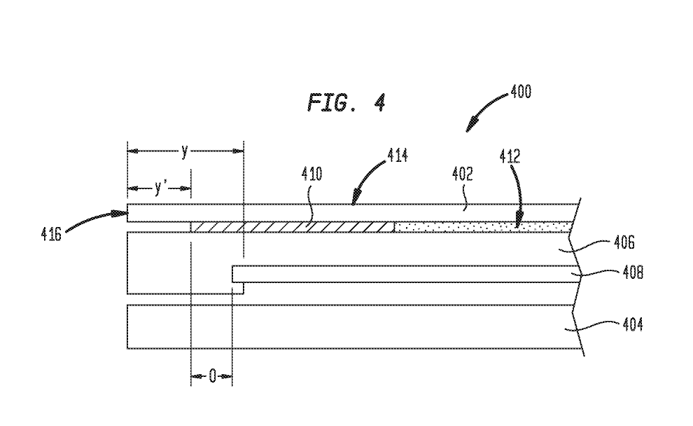

FIG. 4 is a partial enlarged section view of a portable computer 400 including a protective cover 402. As described above, the portable computer 400 includes a body 404 and a screen housing 406 pivotably connected thereto. The screen housing 406 incorporates the screen 408 and an adhesive strip 410 secures the cover 402 to the rear surface 412 of the screen housing 406. An exposed surface 414 of the cover 402 can be used as a writing surface (e.g., for so-called dry-erase pens) to increase the functionality of the protective cover 402. As can be seen, the edge of the adhesive strip 410 is disposed a distance y′ from the minor edge 416 of the protective cover 402, as that distance y′ is defined above. Distance y, as defined above, is also depicted. One reason that adhesive strips 410 placed at distance y′ from the edge 416 may display improved performance (over strips placed at distance y) is because of the overlap o between the adhesive strip 410 and the portion of the screen housing 406 that supports the screen 408. This is interesting, since it appears then that protection is not simply afforded by use of the cover 402, but may also be effected by the bridging nature of the adhesive strip 410.

While there have been described herein what are to be considered exemplary and preferred examples of the present technology, other modifications of the technology will become apparent to those skilled in the art from the teachings herein. The particular methods of manufacture and geometries disclosed herein are exemplary in nature and are not to be considered limiting. It is therefore desired to be secured in the appended claims all such modifications as fall within the spirit and scope of the technology. Accordingly, what is desired to be secured by Letters Patent is the technology as defined and differentiated in the following claims, and all equivalents.

What is claimed is:

1. A protective cover for a portable computer, the protective cover comprising:
a central core comprising a first material;
an outer shell disposed about the central core, wherein the outer shell comprises a perimeter having a pair of opposed major edges and a pair of opposed minor edges, and wherein the outer shell comprises a second material different than the first material, and wherein the pair of opposed major edges defines an outer shell width therebetween, and wherein the pair of opposed minor edges defines an outer shell length therebetween; and
an adhesive strip disposed on a first side of the outer shell, wherein the adhesive strip comprises an adhesive strip width and an adhesive strip height less than the adhesive strip width, wherein the adhesive strip is disposed such that the adhesive strip width is substantially parallel to the pair of opposed major edges, and wherein the adhesive strip is spaced from at least one of the pair of opposed major edges by a first spacing substantially one-half the adhesive strip height, and wherein the adhesive strip is spaced from at least one of the pair of opposed minor edges by a second spacing approximately equal to the adhesive strip height.

2. The protective cover of claim 1, wherein the second spacing does not exceed the adhesive strip height.

3. The protective cover of claim 1, wherein the adhesive strip height is approximately one-half inch.

4. The protective cover of claim 1, wherein the adhesive strip comprises two adhesive strips, wherein the two adhesive strips are disposed proximate a single one of the pair of opposed major edges.

5. The protective cover of claim 4, wherein the two adhesive strips are separated from each other by a gap having a gap distance of less than the adhesive strip width.

6. The protective cover of claim 1, wherein the adhesive strip comprises four adhesive strips, wherein a first two of the four adhesive strips are disposed proximate a first one of the pair of opposed major edges, and wherein a second two of the four adhesive strips are disposed proximate a second one of the pair of opposed major edges.

7. The protective cover of claim 1, wherein a single one of the pair of opposed major edges is connected to a single one of the pair of opposed minor edges at a curved portion of the perimeter, wherein the curved portion of the perimeter comprises a radius substantially similar to the second spacing.

8. The protective cover of claim 1 wherein the first material is plastic and wherein the second material is metal.

9. The protective cover of claim 8, wherein the first material is PVC and wherein the second material is aluminum.

10. The protective cover of claim 1, wherein the second material comprises a substantially erasable writing surface.

11. A protective cover for a portable computer, the protective cover comprising:
a shell comprising a perimeter defined at least in part by a major edge and a minor edge and a curved edge joining the major edge and the minor edge; and
an adhesive strip comprising an elongate axis, wherein the elongate axis is disposed substantially parallel to the major edge, and wherein outer edges of the adhesive strip are disposed a first distance from the major edge and are disposed a second distance from the minor edge, wherein the second distance is greater than the first distance, and wherein the second distance is substantially similar to a height of the adhesive strip.

12. The protective cover of claim 11, wherein the shell substantially surrounds a core material different than the shell.

13. The protective cover of claim 11, wherein the curved edge comprises a radius substantially the same as the second distance.

14. The protective cover of claim 11, wherein the adhesive strip comprises a strip width at least about approximately one-third of a length of the major edge.

15. The protective cover of claim 11, wherein the adhesive strip comprises a removable cover.

16. The protective cover of claim 11, wherein the second distance is no more than substantially double the first distance.

17. The protective cover of claim 16, wherein the first distance is about one-quarter inch.

18. The protective cover of claim 11, wherein the perimeter comprises four curved edges.

19. The protective cover of claim 18, wherein the adhesive strip comprises four adhesive strips, wherein a single one of the four adhesive strips is disposed proximate a single one of the four curved edges.

20. The protective cover of claim 11, wherein the adhesive strip comprises a foam material.
